(19) United States
(12) Patent Application Publication
(10) Pub. No.: US 2023/0317635 A1
(43) Pub. Date: Oct. 5, 2023

(54) RF CHIP, STRUCTURE AND METHOD FOR RF CHIP GUARD-RING ARRANGEMENT

(71) Applicant: Chengdu Sicore Semiconductor Corp. Ltd., Chengdu (CN)

(72) Inventor: Cemin Zhang, Chino, CA (US)

(73) Assignee: Chengdu Sicore Semiconductor Corp. Ltd., Chengdu (CN)

(21) Appl. No.: 17/835,643

(22) Filed: Jun. 8, 2022

(30) Foreign Application Priority Data
Mar. 29, 2022 (CN) 202210320289.X

(51) Int. Cl. H01L 23/00; H01L 23/528; H01L 23/64

(52) U.S. Cl. CPC H01L 23/564; H01L 23/64; H01L 23/5286; H01L 23/562

(57) ABSTRACT

Various embodiments for guard ring arrangement on low-k dielectric materials to reduce moisture ingress effect are disclosed in the present disclosure. Embodiments of a double guard ring structure comprising an outer guard ring and an inner guard ring are disclosed. The double guard ring structure has an outer slit and an inner slit opposite to each other for an open loop structure to avoid inductive coupling during RF signal transmission. With lengthened moisture ingress paths, the double guard ring structure enables easy implementation. Disclosed also are embodiments of a closed guard ring structure in a flipped RF chip. The closed guard ring has one or more ground bumping pads disposed inside and grounded via bumping pillars to a top ground layer of a substrate. Furthermore, the ground bumping pads and the RF signal bumping pad may form a ground-signal-ground (GSG) pad structure for a smooth RF transmission.

### BACKGROUND

### A. Technical Field

The present invention relates generally to semiconductor structures, and more particularly to guard ring arrangement for semiconductor chip operating at radio frequencies.

### B. Background of the Invention

Radio frequency (RF) or microwave/millimeter-wave frequency circuits typically comprise dielectric material, which may consume excessive dielectric heating power under high RF frequency. For improvements in RF circuitry performance, especially for higher RF frequency, low dielectric constant (low-k) porous materials, e.g., SiCOH or p-SiCOH, have been widely used in various advanced RF integrated circuits (ICs).

However, the low-k porous materials absorb much more moisture compared to non-porous conventional dielectric material, such as SiO₂ film via chemical vapor deposition (CVD-SiO₂). To prevent moisture ingress into an RF chip which may cause SiCOH cracking or degrade chip reliability (e.g., electromigration, stress migration, etc.), a chip guard ring formed by a stack of back end of the line (BEOL) metal structures that laterally surrounds the semiconductor chip has been adopted. The chip guard ring may prevent ionic contaminants and act as a film delamination barrier from environmental exposure during reliability stressing and normal usage.

Some chip guard ring (or seal ring) may comprise substrate-contacted metals to provide a low resistance path to chip substrate ground for surge currents. At RF or microwave/millimeter-wave frequencies, continuous guard rings may cause inductive coupling, and thus bring interference for on-chip signal path.

Accordingly, there is a need for systems and methods for arranging guard rings for semiconductor RF chip with improved performance.

### SUMMARY OF THE INVENTION

The present disclosure provides system and method embodiments of arranging guard rings in semiconductor RF chip for improved performance.

Embodiments of a double guard ring structure comprising an outer guard ring and an inner guard ring are disclosed. Each guard ring may be formed by a stack of back-end-of-line (BEOL) metal structures across multiple layers. The BEOL metal structures laterally surround the low-k porous dielectric materials. The double guard ring structure has an outer slit on the outer guard ring and an inner slit on the inner guard ring for an opening ring structure to avoid inductive coupling during RF signal transmission. Such an opening structure allows multiple moisture ingress paths, e.g., a first moisture ingress path and a second moisture ingress path, between the outer slit and the inner slit. In one or more embodiments, the outer slit is at an opposite location from the inner slit such that the first moisture ingress path and the second moisture ingress path are equal in length. In this way, there is no “short path” for moisture ingress. Ambient moisture always needs to travel a lengthened distance, around half the circumference of the guard ring, to enter the semiconductor chip. Accordingly, moisture ingress effect is greatly reduced or slowed. The slits on both rings break the metal loop thus minimize on-chip RF signal parasitic coupling and inductive coupling caused by closed guard ring. Given the lengthened moisture ingress paths, the double guard ring structure may avoid the complex and costly slit seal and thus make such a structure easier for implementation.

Disclosed also are embodiments of a closed guard ring structure in a flipped RFchip. The closed guard ring has one or more ground bumping pads disposed inside. The closed guard ring may be formed by a stack of BEOL metal structures across multiple layers to laterally enclose the low-k porous dielectric materials. The RF chip may be a flipped chip and comprise an insulator layer and a handling wafer above the multiple layers (after chip flipped). The closed guard ring may be connected to ground bumping pads, which are attached, via bumping pillars, to a top ground layer of a substrate. The top ground layer may be electrically connected to a bottom ground layer via one or more ground vias disposed in the substrate. By such flipped chip connection method, the closed guard ring may be grounded without relying on vias through the handling wafer for grounding, and thus easier for implementation.

Furthermore, the ground bumping pads may be disposed on both sides of an RF signal bumping pad to construct a ground-signal-ground (GSG) pad structure with a characteristic impedance matching the characteristic impedance of the RF signal path for a smooth or low loss RF signal transmission into or out of the RF chip. The ground bumping pillars and the signal bumping pillar may also form a GSG pillar structure having a characteristic impedance matching the GSG pad structure. With characteristic impedance matching, a voltage standing wave ratio (VSWR) equal to or less than 2:1 may be achieved during RF signal transmission.

### BRIEF DESCRIPTION OF THE DRAWINGS

Reference will be made to exemplary embodiments of the present invention that are illustrated in the accompanying figures. Those figures are intended to be illustrative, rather than limiting. Although the present invention is generally described in the context of those embodiments, it is not intended by so doing to limit the scope of the present invention to the particular features of the embodiments depicted and described.

FIG. 1 depicts a prior art RF chip with a continuous guard ring.

FIG. 2 depicts a layout diagram of a double guard ring structure with opposite splits, according to one or more embodiments of the invention.

FIG. 3 depicts a cross-sectional view of the double guard ring structure, according to one or more embodiments of the invention.

FIG. 4 depicts a layout diagram of a variant of double guard ring structure with multiple slits for each ring, according to one or more embodiments of the invention.

FIG. 5 depicts a layout diagram of a closed guard ring structure, according to one or more embodiments of the invention.

FIG. 6 depicts a cross-sectional view of a flipped chip with a closed guard ring structure, according to one or more embodiments of the invention.

FIG. 7 depicts a layout diagram of an RF chip with a closed guard ring structure and a ground-signal-ground (GSG) pad structure for RF signal transmission, according to one or more embodiments of the invention.

FIG. 8 depicts a cross-sectional view of the RF chip and the GSG pillar structure for RF signal transmission, according to one or more embodiments of the invention.

One skilled in the art will recognize that various implementations and embodiments of the invention may be practiced in accordance with the specification. All of these implementations and embodiments are intended to be included within the scope of the invention.

### DETAILED DESCRIPTION OF THE PREFERRED EMBODIMENTS

In the following description, for purpose of explanation, specific details are set forth in order to provide an understanding of the present invention. The present invention may, however, be practiced without some or all of these details. The embodiments of the present invention described below may be incorporated into a number of different electrical components, circuits, devices, and systems. Structures and devices shown in block diagram are illustrative of exemplary embodiments of the present invention and are not to be used as a pretext by which to obscure broad teachings of the present invention. Connections between components within the figures are not intended to be limited to direct connections. Rather, connections between components may be modified, re-formatted, or otherwise changed by intermediary components.

When the specification makes reference to “one embodiment” or to “an embodiment” it is intended mean that a particular feature, structure, characteristic, or function described in connection with the embodiment being discussed is included in at least one contemplated embodiment of the present invention. Thus, the appearance of the phrase, “in one embodiment,” in different places in the specification does not constitute a plurality of references to a single embodiment of the present invention.

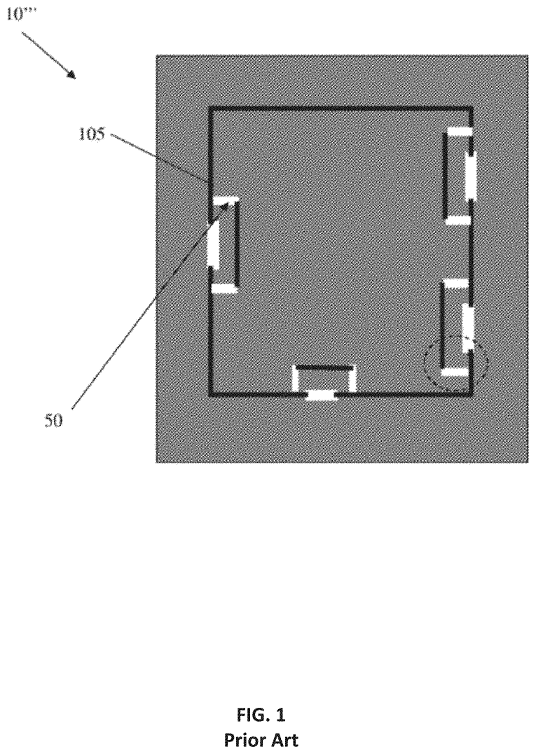

Guard ring technologies are used in many different semiconductor technologies such as GaAs, SiGe, RFCMOS, and RF silicon on insulator (RFSOI). A traditional RF chip with continuous guard ring is shown in FIG. 1. However, at RF or microwave frequencies, continuous guard rings may cause inductive coupling, and thus bring interference for on-chip signal path. To avoid parasitic coupling and inductive coupling, segmented guard rings may be used. However, when a guard ring has a slit, moisture penetration from the dicing edge via the slit may happen. The use of a segmented guard ring can cause reliability failures in low-k porous dielectric materials. Accordingly, RFSOI chips with segmented guard ring and low-K SiCOH or p-SiCOH MOL/BEOL are traditionally incompatible.

Described herein are embodiments of guard rings that may be efficiently constructed around low-k porous dielectric materials for RF chip to reduce or slow moisture ingress effect.

### Embodiment 1

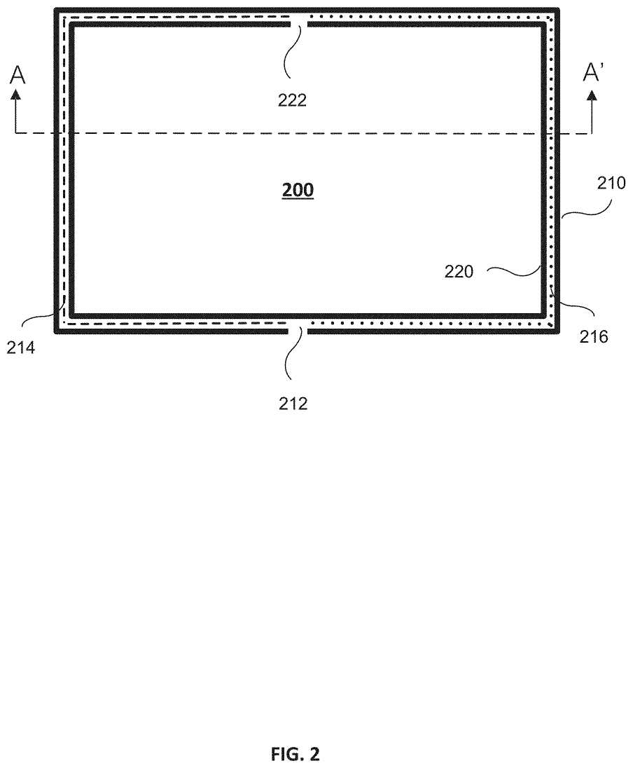

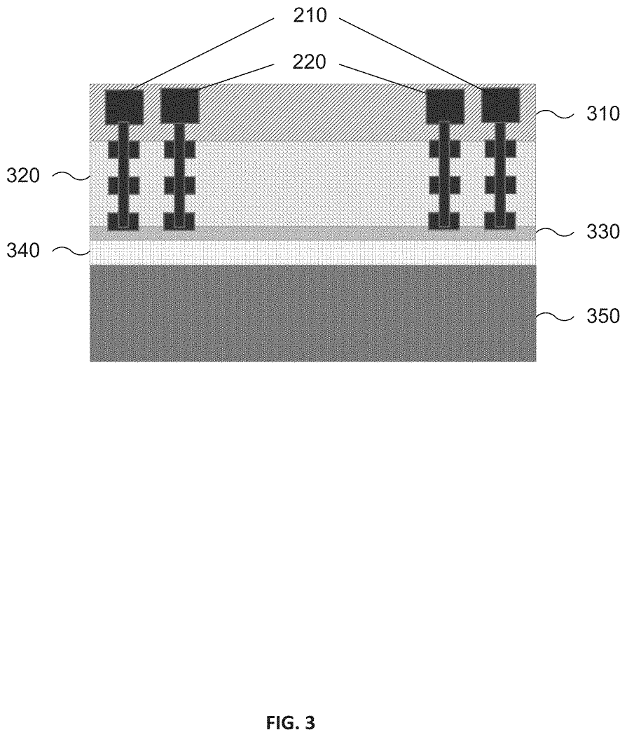

FIG. 2 depicts a layout diagram of a double guard ring structure 200 with opposite splits, according to one or more embodiments of the invention. The double guard ring structure 200 comprises an outer guard ring 210 and an inner guard ring 220. The two guard rings are preferably parallel to each other such that the distance between the two rings is uniform along the guard rings. Each guard ring may be formed by a stack of back-end-of-line (BEOL) metal structures across a film (e.g., Oxide or SiN) layer 310, the porous layer 320, and a semiconductor layer 330, as shown in the cross-sectional view (along the line A-A′ on FIG. 2), shown in FIG. 3. The double guard ring structure 200 sits above an insulator layer 340 and a handling wafer 350. The outer guard ring 210 and the inner guard ring 220 may be grounded or electrically floating with no electrical connection from the semiconductor chip.

As shown in FIG. 2 and FIG. 3, the BEOL metal structures laterally surround a semiconductor RF chip, especially the low-k porous dielectric materials. The double guard ring structure 200 has an outer slit 212 on the outer guard ring 210 and an inner slit 222 on the inner guard ring 220 for an opening ring structure to avoid inductive coupling during RF signal transmission. Such an opening structure allows multiple moisture ingress paths, e.g., a first moisture ingress path 214 and a second moisture ingress path 216, between the outer slit 212 and the inner slit 222.

In one or more embodiments, the outer slit 212 is at an opposite location from the inner slit 214, as shown in FIG. 2, such that the first moisture ingress path 214 and the second moisture ingress path 216 are equal in length. In this way, there is no “short path” for moisture ingress. Ambient moisture always needs to travel a lengthened distance, around half the circumference of the guard ring, to enter the semiconductor chip. Accordingly, moisture ingress effect is greatly reduced or slowed. When fabrication process allowed, the spacing between the outer guard ring 210 and inner guard ring 220 needs to be as small as possible, leading to a narrow ingress path that further help to slow down the moisture ingress effect. The slits on both rings break the metal loop thus minimize on-chip RF signal parasitic coupling and inductive coupling caused by closed guard ring. Given the lengthened moisture ingress paths, the double guard ring structure 200 may avoid the complex and costly slit seal and thus make such a structure easier for implementation.

One skilled in the art shall understand that the opposite location of the outer slit 212 from the inner slit 214 shown in FIG. 2 is exemplary. For example, the outer slit 212 and the inner slit 214 may be located at opposite corners instead of at middle points of opposite sides. Such variations are still within the scope of the present patent disclosure.

One skilled in the art shall understand that the concept of the double guard ring structure may be extended to beyond two rings. For example, one or more additional guard rings with slits may be added besides the double guard ring structure to make the moisture ingress path even longer. Such variations are also within the scope of the present patent disclosure.

### Embodiment 2

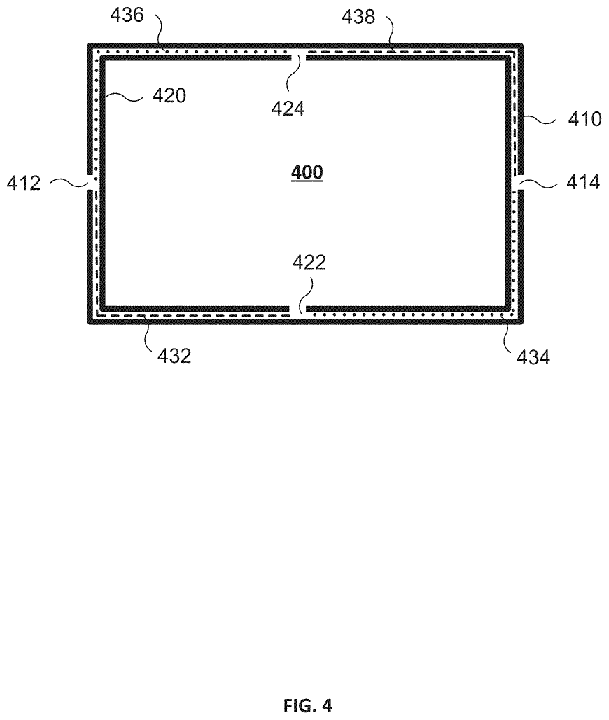

As for the RF chip, when frequency gets higher or the chip size gets larger, the effects of on chip RF signal parasitic coupling and inductive coupling will gets worse, more slits may needed to minimize such effects. FIG. 4 depicts a layout diagram of a variant of double guard ring structure 400 with multiple slits for each ring, according to one or more embodiments of the invention. The double guard ring structure 400 comprises an outer guard ring 410 and an inner guard ring 420. The outer guard ring 410 has a first outer slit 412 and a second outer slit 414 opposite to each other. The inner guard ring 420 has a first inner slit 422 and a second inner slit 424 opposite to each other. In one or more embodiments, the line connecting the outer slits 412/414 and the inner slit 422/424 may form a cyclic symmetric configuration, e.g., inner slits at middle point of horizontal sides of the inner guard ring 420 and outer slits at middle point of vertical sides of outer guard ring 410 as shown in FIG. 4. Such a cyclic symmetric opening structure allows multiple moisture ingress paths, e.g., a first moisture ingress path 432, a second moisture ingress path 434, a third moisture ingress path 436, and a fourth moisture ingress path 438, of equal length around a quarter of the circumference of the guard ring. The uniformity of moisture ingress paths ensures that there is no “short-cut” for moisture ingress and thus slows or reduces moisture ingress effect.

### Embodiment 3

Although double or more guard rings with slits can slow or delay the moisture ingress and thus improve the chip moisture sensitivity level, split guard rings may not prevent moisture ingress theoretically. When an RF circuit operates in higher frequency or the die size becomes larger, more slits may be required and thus be more vulnerable from moisture ingress effect.

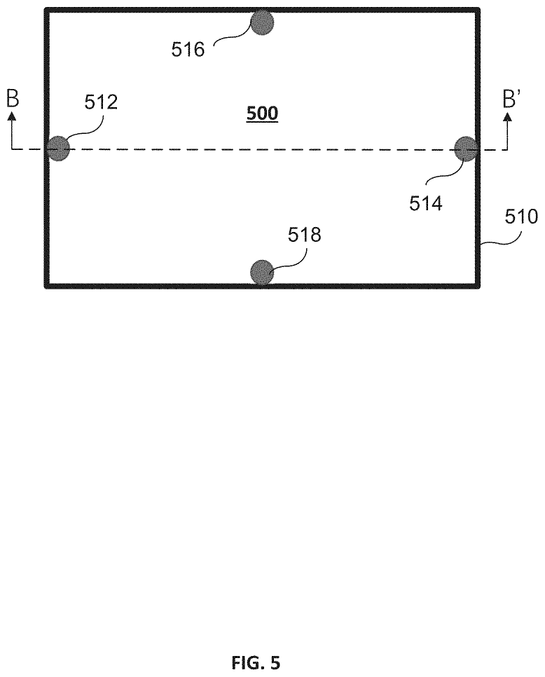

FIG. 5 depicts a layout diagram of a closed guard ring structure, according to one or more embodiments of the invention. The closed guard ring structure 500 comprises a closed guard ring 510 and at least one ground bumping pad disposed inside and electrically connected to the closed guard ring 510. As shown in FIG. 5, the at least one ground bumping pad may comprise a first ground bumping pad 512, a second ground bumping pad 514, a third ground bumping pad 516, and a fourth ground bumping pad 518 disposed along each side of the closed guard ring 510. These ground bumping pads may be connected to corresponding GND bumping pillars and thus ground the closed guard ring 510.

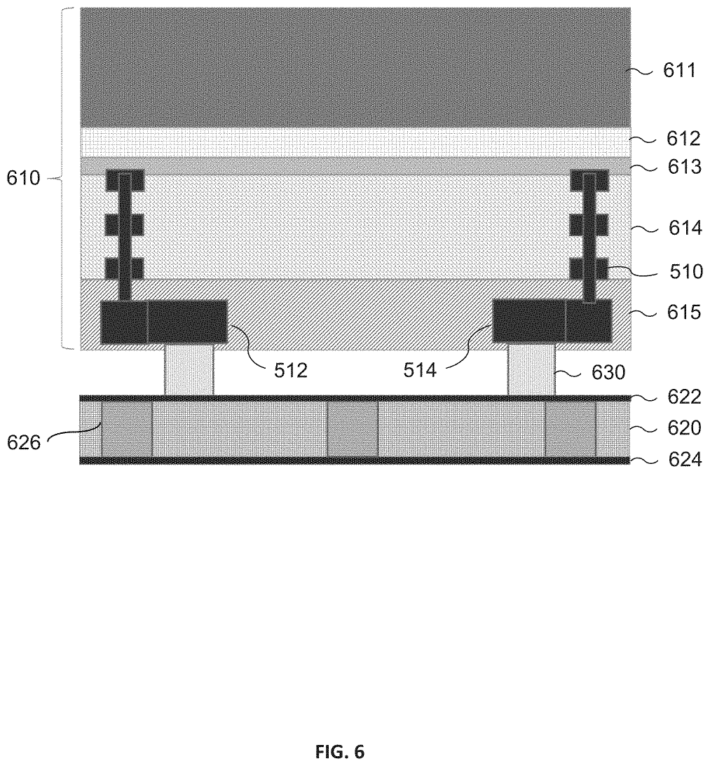

FIG. 6 depicts a cross-sectional view along the line B-B′ (in FIG. 5) of a flipped chip 610 with a closed guard ring structure, according to one or more embodiments of the invention. The closed guard ring 510 may be formed by a stack of BEOL metal structures across a film (e.g., Oxide or SiN) layer 615, the porous layer 614, and a semiconductor layer 613. The chip 610 is a flipped chip and comprises an insulator layer 612 and a handling wafer 611 above the semiconductor layer 613 (after chip flipped). The closed guard ring 510 is connected to ground bumping pads 512 and 514, which are attached, via bumping pillars 630, to atop ground layer 622 of a substrate 620. The top ground layer 622 may be electrically connected to a bottom ground layer 624 via one or more ground vias 626 disposed in the substrate 620. By such flipped chip connection method, the closed guard ring 510 may be grounded without relying on vias through the handling wafer for grounding, and thus easier for implementation.

The guard ring structure shown in FIG. 5 and FIG. 6 has no slit cuts in the metal loop thus minimizes the moisture ingress effect. At the same time, the effect of on chip RF signal parasitic coupling and inductive coupling is reduced by grounding the guard ring to a substrate ground layer through the ground bumping pads and bumping pillars. The parasitic coupling signals on guard ring are directed to ground instead of impacting the on-chip RF circuit. Preferably, the guard ring is grounded via at least one ground bumping pad. The more ground bumping pads are connected to the guard ring, the less parasitic coupling and inductive coupling occur.

### Embodiment 4

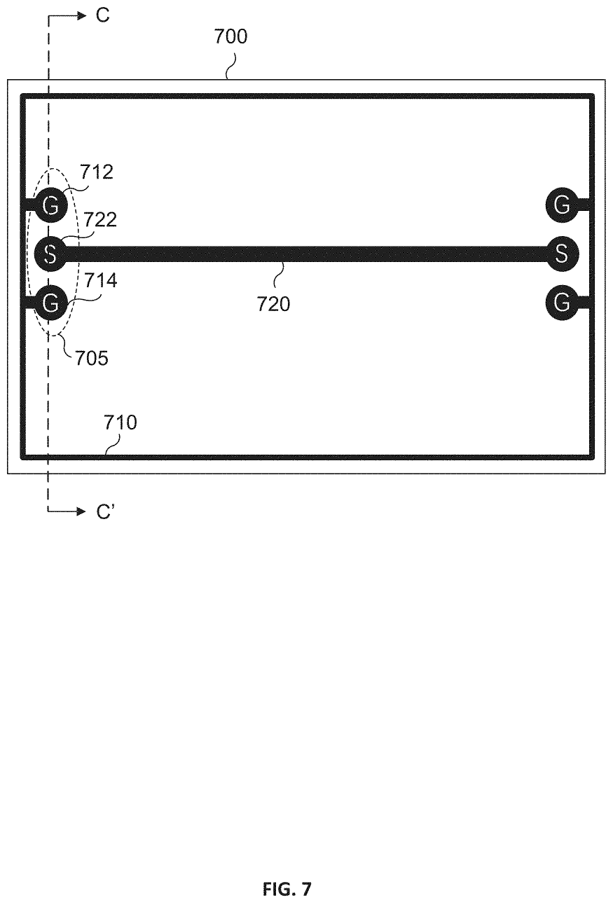

FIG. 7 depicts a layout diagram of an RF chip 700 with a closed guard ring structure and a GSG pad structure for RF signal transmission, according to one or more embodiments of the invention. The guard ring 710 is a closed loop without slit. A plurality of the ground bumping pads are disposed inside the guard ring 710 and electrically connected to the guard ring 710. Furthermore, the ground bumping pads 712/714 are disposed on both sides of the RF signal bumping pad 722 to construct a GSG pad structure 705, that has a characteristic impedance matching the characteristic impedance of the RF signal path 720 for a smooth or low loss RF signal transmission into or out of the RF chip 700.

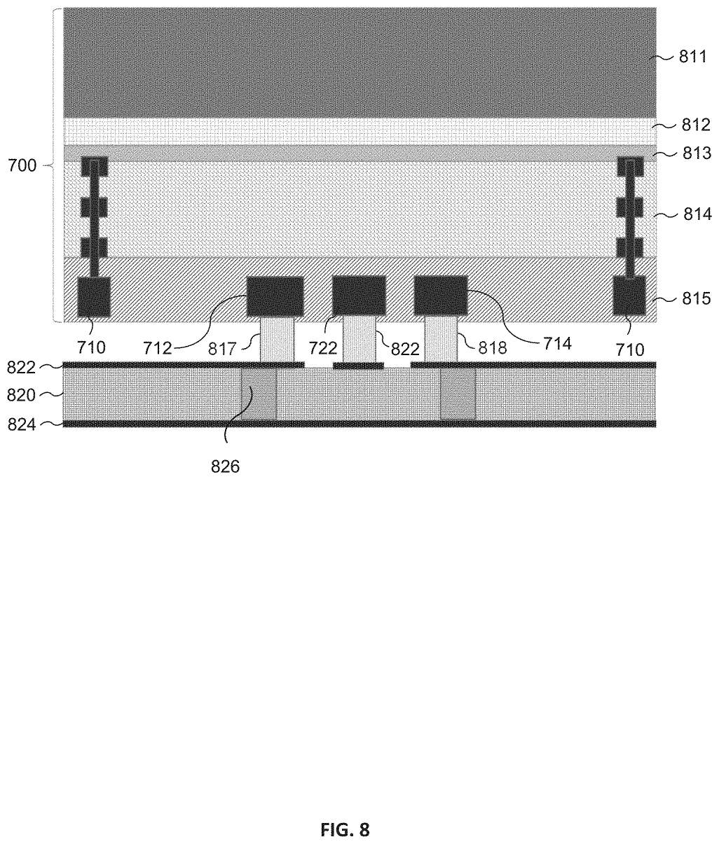

FIG. 8 depicts a cross-sectional view (along the line C-C′ in FIG. 7) of the RF chip and the GSG pillar structure for RF signal transmission, according to one or more embodiments of the invention. The closed guard ring 710 may be formed by a stack of BEOL metal structures across a film (e.g., Oxide or SiN) layer 815, the porous layer 814, and a semiconductor layer 813. The chip 610 is a flipped chip and comprises an insulator layer 812 and a handling wafer 811 above the semiconductor layer 813 (after chip flipped). The RF chip 700 is flipped and the ground bumping pads 712/714 are connected to a top ground layer 822 of a substrate 820 (underneath the RF chip) through ground bumping pillars 817 and 818. The top ground layer 822 may be electrically connected to a bottom ground layer 824 via one or more ground vias 826 disposed in the substrate 820. The RF signal bumping pad 722 is connected to a signal bumping pillar 816, disposed between the ground bumping pillars 817 and 818, for RF signal path connection. The ground bumping pillars 817 and 818 and the signal bumping pillar 816 may also form a GSG pillar structure having characteristic impedance matching the GSG pad structure 705. With characteristic impedance matching, a voltage standing wave ratio (VSWR) equal to or less than 2:1 may be achieved during RF signal transmission.

Although aforementioned chip embodiment in FIG. 7 has a straight signal path for simplicity, one skilled in the art shall understand that a chip may be a signal source chip only having one interface for signal output, a signal divider having one signal input interface and multiple output interfaces, or a signal combiner having multiple signal input interfaces and one output interface, etc. Embodiments of the abovementioned characteristic impedance matching between the GSG pad structure and the GSG pillar structure may be applicable for each input or output signal interface. One skilled in the art shall also understand the ground bumping pad and the RF signal bumping pad may also form a ground-signal (GS) or a signal-ground (SG) pad structure instead of a GSG pad structure. Similarly, the ground bumping pillar and the signal bumping pillar may form a GS (or SG) pillar structure instead of a GSG pillar structure. Such variations shall also be within the scope of the present patent disclosure.

The foregoing description of the invention has been described for purposes of clarity and understanding. It is not intended to limit the invention to the precise form disclosed. Various modifications may be possible within the scope and equivalence of the appended claims.

It will be appreciated to those skilled in the art that the preceding examples and embodiments are exemplary and not limiting to the scope of the present invention. It is intended that all permutations, enhancements, equivalents, combinations, and improvements thereto that are apparent to those skilled in the art upon a reading of the specification and a study of the drawings are included within the true spirit and scope of the present invention.

It shall also be noted that elements of the claims, below, may be arranged differently including having multiple dependencies, configurations, and combinations. For example, in embodiments, the subject matter of various claims may be combined with other claims.

1. A guard-ring structure for radio-frequency (RF) chip comprising:
a layer of porous dielectric material;
an inner guard ring laterally surrounding the layer of porous dielectric material, the inner guard ring comprises an inner slit; and
an outer guard ring laterally surrounding the inner guard ring, the outer guard ring comprises an outer slit opposite to the inner slit to allow a first and a second moisture ingress paths from the outer slit to the inner slit.

2. The guard-ring structure for RF chip of claim 1 wherein the inner guard ring and the outer guard ring are parallel to each other.

3. The guard-ring structure for RF chip of claim 1 wherein the inner guard ring and the outer guard ring comprise of a stack of back-end-of-line (BEOL) metal structure.

4. The guard-ring structure for RF chip of claim 3 wherein the BEOL metal structure is across a film layer, the layer of porous dielectric material, and a semiconductor layer.

5. The guard-ring structure for RF chip of claim 3 wherein the BEOL metal structure is electrically floating.

6. The guard-ring structure for RF chip of claim 1 wherein the first and the second moisture ingress paths are equal in length.

7. A radio-frequency (RF) chip comprising:
a layer of porous dielectric material;
a closed guard ring laterally surrounding the layer of porous dielectric material, the closed guard ring comprises a stack of back-end-of-line (BEOL) metal structure; and
a first ground bumping pad disposed inside and electrically connected to the closed guard ring, the first ground bumping pad connects to a ground layer of a substrate via a first ground bumping pillar.

8. The RF chip of claim 7 wherein the RF chip is a flipped RF chip.

9. The RF chip of claim 7 further comprising:
a second ground bumping pad disposed inside and electrically connected to the closed guard ring, the second ground bumping pad connects to the ground layer of the substrate via a second ground bumping pillar.

10. The RF chip of claim 7 wherein the BEOL metal structure crosses a film layer, the layer of porous dielectric material, and a semiconductor layer.

11. The RF chip of claim 9 further comprising:
An RF signal bumping pad coupled to an RF signal path in the RF chip, the first ground bumping pad, the second ground bumping pad and the RF signal bumping pad form a ground-signal-ground (GSG) pad structure.

12. The RF chip of claim 11 wherein the GSG pad structure has a characteristic impedance matching a characteristic impedance of the RF signal path.

13. The RF chip of claim 12 wherein the RF signal bumping pad connects to a signal bumping pillar for RF signal transmission, the first ground bumping pillar, the second ground bumping pillar, and the signal bumping pillar form a GSG pillar structure.

14. The RF chip of claim 13 wherein the GSG pillar structure has a characteristic impedance matching the characteristic impedance of the RF signal path.

15. A method for RF chip guard-ring arrangement comprising:
forming a closed guard ring that laterally surrounds a layer of porous dielectric material in a flipped radio-frequency (RF) chip, the closed guard ring comprises a stack of back-end-of-line (BEOL) metal structure; and
disposing a first ground bumping pad inside the closed guard ring, the first ground bumping pad is electrically connected to the closed guard ring; and
connecting the first ground bumping pad to a ground layer of a substrate via a first ground bumping pillar.

16. The method of claim 15 further comprising:
disposing a second ground bumping pad inside the closed guard ring, the second ground bumping pad is electrically connected to the closed guard ring; and
connecting the second ground bumping pad to the ground layer of the substrate via a second ground bumping pillar.

17. The method of claim 15 wherein the BEOL metal structure crosses a film layer, the layer of porous dielectric material, and a semiconductor layer.

18. The method of claim 16 further comprising:
coupling an RF signal bumping pad to an RF signal path in the flipped RF chip, the first ground bumping pad, the second ground bumping pad and the RF signal bumping pad form a ground-signal-ground (GSG) pad structure.

19. The method of claim 18 wherein the GSG pad structure has a characteristic impedance matching a characteristic impedance of the RF signal path.

20. The method of claim 18 further comprising:
connecting the RF signal bumping pad to a signal bumping pillar for RF signal transmission, the first ground bumping pillar, the second ground bumping pillar, and the signal bumping pillar form a GSG pillar structure.
